(19) United States
(12) Patent Application Publication
(10) Pub. No.: US 2016/0079216 A1
(43) Pub. Date: Mar. 17, 2016

(54) SEMICONDUCTOR DEVICE, AND METHOD FOR MANUFACTURING SEMICONDUCTOR DEVICE

(71) Applicant: Kabushiki Kaisha Toshiba, Tokyo (JP)

(72) Inventor: Eiichi Hosomi, Kawasaki Kanagawa (JP)

(21) Appl. No.: 14/645,343

(22) Filed: Mar. 11, 2015

(30) Foreign Application Priority Data
Sep. 11, 2014 (JP) 2014-185365

(51) Int. Cl. H01L 25/16; H01L 21/768; H01L 23/48; H01L 21/78; H01L 23/00; H01L 25/00; H01L 21/683

(52) U.S. Cl. CPC H01L 25/16; H01L 25/50; H01L 21/76898; H01L 21/6835; H01L 21/78; H01L 24/81; H01L 23/481; H01L 24/17; H01L 24/49; H01L 24/73; H01L 24/97; H01L 2221/68327; H01L 2221/68359; H01L 2221/68381; H01L 2924/146; H01L 2924/14335; H01L 2924/143; H01L 2224/16055; H01L 2224/16145; H01L 2224/16225; H01L 2224/48106; H01L 2224/48145; H01L 2224/73257; H01L 2924/1434

(57) ABSTRACT

According to one embodiment, there is provided a semiconductor device including a first semiconductor chip and a second semiconductor chip. The second semiconductor chip is mounted on a back surface of the first semiconductor chip. The first semiconductor chip includes a substrate, a back surface wiring, a multi-layer wiring, a through silicon via, and a front surface electrode. The back surface wiring is arranged on a back surface of the substrate. The back surface wiring is electrically connected to a terminal of the second semiconductor chip. The multi-layer wiring is arranged on a front surface of the substrate. The through silicon via is configured to electrically connect the back surface wiring and the multi-layer wiring through the substrate. The front surface electrode is arranged on the multi-layer wiring and electrically connected to the multi-layer wiring.

### CROSS-REFERENCE TO RELATED APPLICATIONS

This application is based upon and claims the benefit of priority from Japanese Patent Application No. 2014-185365, filed on Sep. 11, 2014; the entire contents of which are incorporated herein by reference.

### FIELD

Embodiments described herein relate generally to a semiconductor device, and a method for manufacturing the semiconductor device.

### BACKGROUND

In order to enhance a mounting density, a plurality of semiconductor chips is stacked in a semiconductor device. In other words, a support substrate is laminated to a semiconductor substrate to thin the semiconductor substrate, and thereafter, the support substrate is stripped from the semiconductor substrate. The semiconductor substrate is then singulated to obtain semiconductor chips, and the plurality of semiconductor chips are stacked to obtain the semiconductor device. In this case, it is desirable that the manufacturing cost of the semiconductor device is reduced.

### BRIEF DESCRIPTION OF THE DRAWINGS

FIG. 1 is a cross-sectional view illustrating a configuration of a semiconductor device according to a first embodiment;

FIG. 2 is a block diagram illustrating the configuration of the semiconductor device according to the first embodiment;

FIGS. 3A to 3C are cross-sectional views illustrating a method for manufacturing the semiconductor device according to the first embodiment;

FIGS. 4A to 4C are cross-sectional views illustrating the method for manufacturing the semiconductor device according to the first embodiment;

FIGS. 5A to 5C are cross-sectional views illustrating the method for manufacturing the semiconductor device according to the first embodiment;

FIGS. 6A and 6B are cross-sectional views illustrating the method for manufacturing the semiconductor device according to the first embodiment;

FIG. 7 is a cross-sectional view illustrating a configuration of a semiconductor device according to a second embodiment;

FIGS. 8A to 8C are cross-sectional views illustrating a method for manufacturing the semiconductor device according to the second embodiment;

FIGS. 9A and 9B are cross-sectional views illustrating the method for manufacturing the semiconductor device according to the second embodiment;

FIG. 10 is a cross-sectional view illustrating a configuration of a semiconductor device according to a third embodiment;

FIG. 11 is a block diagram illustrating a configuration of the semiconductor device according to the third embodiment;

FIGS. 12A to 12C are cross-sectional views illustrating a method for manufacturing the semiconductor device according to the third embodiment; and

FIGS. 13A and 13B are cross-sectional views illustrating the method for manufacturing the semiconductor device according to the third embodiment.

### DETAILED DESCRIPTION

In general, according to one embodiment, there is provided a semiconductor device including a first semiconductor chip and a second semiconductor chip. The second semiconductor chip is mounted on a back surface of the first semiconductor chip. The first semiconductor chip includes a substrate, a back surface wiring, a multi-layer wiring, a through silicon via, and a front surface electrode. The back surface wiring is arranged on a back surface of the substrate. The back surface wiring is electrically connected to a terminal of the second semiconductor chip. The multi-layer wiring is arranged on a front surface of the substrate. The through silicon via is configured to electrically connect the back surface wiring and the multi-layer wiring through the substrate. The front surface electrode is arranged on the multi-layer wiring and electrically connected to the multi-layer wiring.

Exemplary embodiments of a semiconductor device will be explained below in detail with reference to the accompanying drawings. The present invention is not limited to the following embodiments.

### First Embodiment

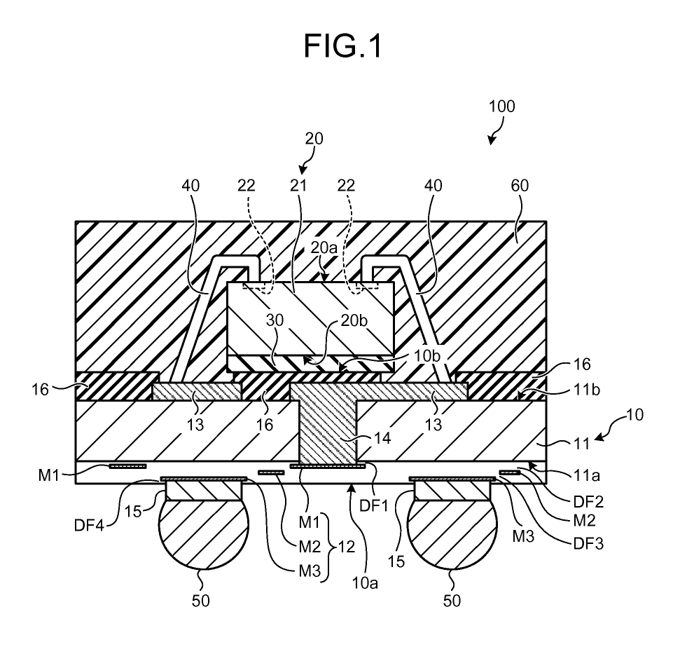

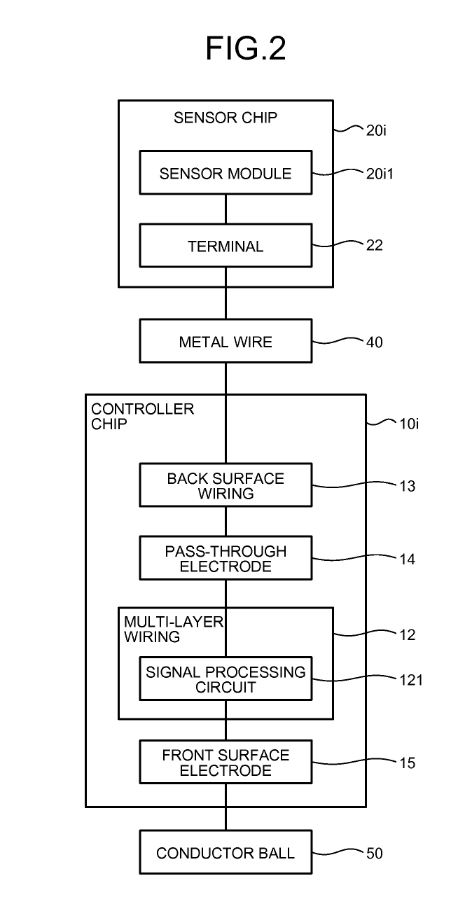

A semiconductor device 100 according to a first embodiment will be described using FIGS. 1 and 2. FIG. 1 is a cross-sectional view illustrating a configuration of the semiconductor device 100. FIG. 2 is a block diagram illustrating the configuration of the semiconductor device 100.

High density mounting is demanded on the semiconductor device 100. For example, a sensor chip such as an acceleration sensor, a geomagnetic sensor, and the like is mounted on a portable device, and the market thereof is being widely spread. The demand on the high density mounting of the semiconductor device including the semiconductor chip such as the sensor chip, and the like is very strong in order to squeeze the function to a limited space in the portable device.

In the semiconductor device 100, a plurality of semiconductor chips is stacked to enhance the mounting density. Furthermore, in the semiconductor device 100, a three-dimensional mounting by a through silicon via (TSV: Through Silicon Via) is carried out as a means for realizing the high density mounting.

Specifically, as illustrated in FIG. 1, the semiconductor device 100 includes a semiconductor chip 10, a semiconductor chip 20, a metal wire 40, a conductor ball 50, and a mold resin 60.

The semiconductor chip 10 includes a substrate 11, a back surface wiring 13, a multi-layer wiring 12, a through silicon via 14, and a front surface electrode 15. The substrate 11 may be formed with a semiconductor, and for example, can be formed with a material having silicon as a main component.

The back surface wiring 13 is disposed on a back surface 11b of the substrate 11. The back surface wiring 13 is electrically connected to the through silicon via 14, and is routed from above the through silicon via 14 to a predetermined position on the back surface 11b. For example, if the through silicon via 14 is arranged at a position overlapping the semiconductor chip 20 when seen through from a direction perpendicular to the back surface 11b, the back surface wiring 13 is routed to a position not overlapping the semiconductor chip 20. The metal wire 40 is joined to the back surface wiring 13, and a terminal 22 of the semiconductor chip 20 is electrically connected through the metal wire 40. The back surface wiring 13 is formed with a material having copper as a main component, for example. Although not illustrated, the back surface 11b of the substrate 11 is covered with an insulating layer, and the back surface wiring 13 is arranged on the insulating layer at the back surface 11b of the substrate 11. The back surface wiring 13 and the substrate 11 are thereby electrically insulated.

An insulating film 16 partially covers the back surface wiring 13, and exposes a vicinity of a region where the metal wire 40 is to be joined in the back surface wiring 13. For example, the insulating film 16 covers a region where the semiconductor chip 20 is to be arranged in plan view. It should be noted that the insulating film 16 is omissible.

The multi-layer wiring 12 is arranged on a front surface 11a of the substrate 11. The multi-layer wiring 12 includes a plurality of wiring layers (e.g., three wiring layers M1 to M3) and a plug wiring (not illustrated) for connecting the wiring layers. Insulating layers DF1 to DF4 and the wiring layers M1 to M3 are alternately and repeatedly stacked on the front surface 11a of the substrate 11 to form a multi-layer wiring structure. Each wiring layer M1 to M3 is formed with a material having aluminum as a main component, for example. Each insulating layer DF1 to DF4 is formed with a material having oxide silicon as a main component, for example.

The through silicon via 14 passes through the substrate 11 from the back surface 11b to the front surface 11a. The through silicon via 14 electrically connects the back surface wiring 13 and the multi-layer wiring 12. The through silicon via 14 is formed with a material having copper as a main component, for example. An end on the front surface 11a side of the substrate 11 in the through silicon via 14 can be connected to the lowermost wiring layer M1 in the multi-layer wiring 12. Although not illustrated, an insulting layer is interposed between the through silicon via 14 and the substrate 11. Thus, the through silicon via 14 and the substrate 11 are electrically insulated.

The front surface electrode 15 is arranged on the multi-layer wiring 12, and is electrically connected to the multi-layer wiring 12. For example, the front surface electrode 15 can be arranged on the uppermost wiring layer (the uppermost wiring) M3 in the multi-layer wiring 12. The front surface electrode 15 can be formed with a material having satisfactory joining property with the material (e.g., solder) of the conductor ball 50 than the material (e.g., aluminum) of each wiring layer M1 to M3 in the multi-layer wiring 12. The front surface electrode 15 may be formed with a material having copper as a main component, or may be formed with a material having nickel/gold alloy as a main component, for example.

The front surface electrode 15 has a planar dimension and shape corresponding to the conductor ball 50. The front surface electrode 15 may, for example, have a circular shape (e.g., circular shape having diameter of 0.2 mm) or a rectangular shape (rectangular shape included in a circle having diameter of 0.2 mm) in plan view. The front surface electrode 15 is arranged at an arrangement interval determined in view of the dimension of the conductor ball 50. The front surface electrode 15 is arranged at an arrangement interval of a pitch of 0.4 mm, for example.

The semiconductor chip 20 is mounted on the back surface 10b of the semiconductor chip 10. For example, the semiconductor chip 20 is mounted on the back surface 10b of the semiconductor chip 10 with the front surface 20a facing toward a side opposite to the semiconductor chip 10. The back surface 20b of the semiconductor chip 20 is adhered to the back surface 10b (front surface of the insulating film 16) of the semiconductor chip 10 with a mount resin 30. The planar dimension of the semiconductor chip 20 is smaller than the planar dimension of the semiconductor chip 10. The semiconductor chip 20 is included in the semiconductor chip 10 when seen through from a direction perpendicular to the back surface 10b. Thus, in the semiconductor chip 10, the back surface wiring 13 can be routed to a position not overlapping the semiconductor chip 20 when seen through from the direction perpendicular to the back surface 10b. In other words, the terminal 22 of the semiconductor chip 20 can be electrically connected to the back surface wiring 13 through the metal wire 40. The semiconductor chip 20 includes a chip main body 21 with a substrate and a multi-layer wiring, for example. The multi-layer wiring (not illustrated) can be arranged on the front surface 20a side with respect to the substrate (not illustrated). The terminal 22 of the semiconductor chip 20 can be assumed as an electrode pad formed on the uppermost wiring layer in the multi-layer wiring.

The metal wire 40 electrically connects the terminal 22 of the semiconductor chip 20 and the back surface wiring 13 of the semiconductor chip 10. The metal wire 40 is formed with a material having copper or gold as a main component, for example.

The conductor ball 50 is joined to the front surface electrode 15 to function as an external electrode. For example, when the semiconductor device 100 is mounted on a set substrate, the conductor ball 50 functions as an electrode connected to the set substrate. The conductor ball 50 is formed with solder, for example.

The mold resin 60 seals a space on the back surface 10b side of the semiconductor chip 10. The mold resin 60 covers the semiconductor chip 20 and the metal wire 40. The mold resin 60 is formed with an epoxy resin, for example.

It should be noted that, the semiconductor device 100 may have a configuration in which the conductor ball 50 is omitted. In this case, the front surface electrode 15 can function as an external electrode.

In the semiconductor device 100, the semiconductor chip 10 and the semiconductor chip 20 can have a similar function with each other. Alternatively, the semiconductor chip 10 and the semiconductor chip 20 may have a function different from each other and associated with each other. The semiconductor chip 20, for example, is a memory chip, a logic chip, or a sensor chip. The sensor may be an acceleration sensor, a magnetic sensor, an optical sensor, and the like.

If the semiconductor chip 20 is a memory chip, the semiconductor chip 10 can be a controller chip including a memory controller for controlling the memory chip.

If the semiconductor chip 20 is a logic chip, the semiconductor chip 10 can be a controller chip including a cooperative control processor for carrying out the cooperative control with the logic chip.

If the semiconductor chip 20 is a sensor chip 20i, the semiconductor chip 10 can be a controller chip 10i including a signal processing circuit for processing a signal of the sensor chip 20i. In this case, the semiconductor device 100 can be configured as illustrated in FIG. 2.

The sensor chip 20i includes an acceleration sensor, a geomagnetic sensor, and the like, for example. The sensor chip 20i includes a sensor module 20i1 and the terminal 22. The sensor module 20i1 is configured to detect a predetermined physical quantity. For example, if the sensor chip 20i is an acceleration sensor, the sensor module 20i1 includes a diaphragm and a piezo resistance element, where the piezo resistance element detects the position change of the diaphragm and outputs the detected signal to the terminal 22. For example, if the sensor chip 20i is the geomagnetic sensor, the sensor module 20i1 includes a current source and a Hall element, where the Hall element detects the magnitude and the direction of the geomagnetism while the current is supplied from the current source and outputs the detected signal to the terminal 22.

The signal output to the terminal 22 is transmitted to the back surface wiring 13 of the controller chip 10i through the metal wire 40. The signal transmitted to the back surface wiring 13 is transmitted to the multi-layer wiring 12 through the through silicon via 14. The signal transmitted to the multi-layer wiring 12 is transmitted to a signal processing circuit 121 in the multi-layer wiring 12 through a predetermined wiring in the multi-layer wiring 12. The signal processing circuit 121 processes the signal, converts the signal to a signal recognizable at outside (e.g., host device to which the semiconductor device 100 is connected) and transmits the signal to the front surface electrode 15. The signal transmitted to the front surface electrode 15 is output to the outside through the conductor ball 50.

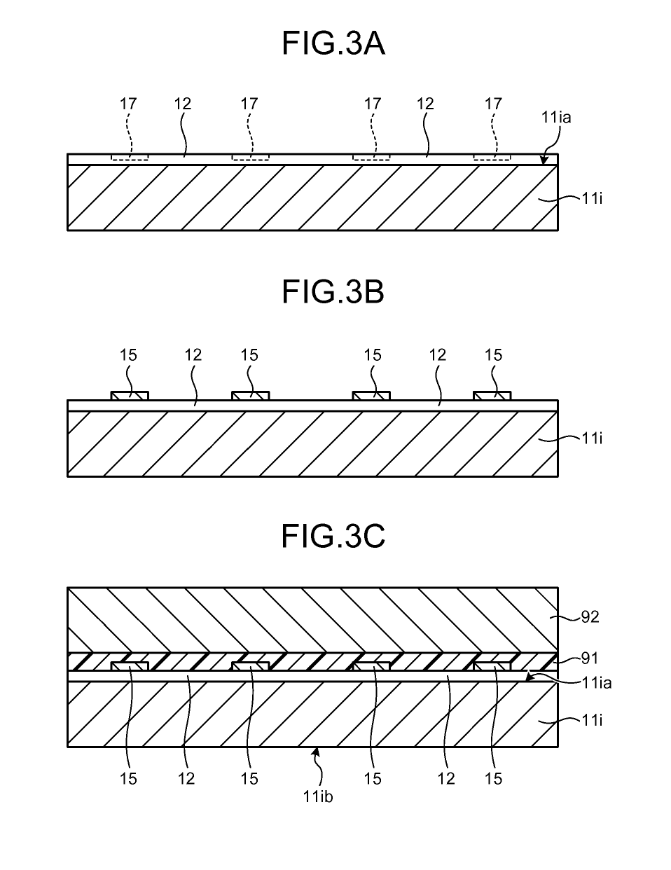

The method for manufacturing the semiconductor device 100 will now be described using FIGS. 3A to 6B. FIGS. 3A to 3C, 4A to 4C, 5A to 5C, 6A, and 6B are step cross-sectional views illustrating the method for manufacturing the semiconductor device 100.

In the step illustrated in FIG. 3A, a semiconductor substrate 11i is prepared. The semiconductor substrate 11i formed with a material having silicon as a main component, for example, may be used. A multi-layer wiring structure including the multi-layer wiring 12 is formed on a front surface 11ia of the semiconductor substrate 11i. In other words, a predetermined patterning is carried out while alternately and repeatedly stacking the insulating layers DF1 to DF4 and the wiring layers M1 to M3 (see FIG. 1). In this case, etching is carried out until the uppermost wiring layer M3 is exposed with a resist pattern RP1 (not illustrated) having an opening pattern corresponding to the region, where the front surface electrode 15 is to be formed, as a mask. An opening 17 is thus formed in the uppermost insulating layer DF4 so that the region, where the front surface electrode 15 is to be formed, in the uppermost wiring layer M3 is exposed. Each insulating layer DF1 to Df4 is formed with a material having oxide silicon as a main component, for example. Each wiring layer M1 to M3 is formed with a material having aluminum as a main component, for example. The opening 17 can be formed to a shape corresponding to the front surface electrode 15 to be formed in plan view. The opening 17 can have a shape including the front surface electrode 15 in plan view.

In the step illustrated in FIG. 3B, the front surface electrode 15 is formed on the multi-layer wiring 12. In this case, the front surface electrode 15 is formed to be electrically connected to the multi-layer wiring 12. For example, the front surface electrode 15 is formed on the region exposed by the opening 17 in the uppermost wiring layer M3 (see FIG. 1). The front surface electrode 15 is formed with a material having satisfactory joining property with the material (e.g., solder) of the conductor ball 50. The front surface electrode 15, for example, is formed with a material having copper as a main component or a material having nickel/gold alloy as a main component. For example, plating is carried out with the resist pattern RP1 as a mask to form the front surface electrode 15. The resist pattern RP1 is then removed.

The front surface electrode 15 is formed to a planar dimension and shape corresponding to the conductor ball 50. The front surface electrode 15 may be formed, for example, to a circular shape (e.g., circular shape having diameter of 0.2 mm) or a rectangular shape (rectangular shape included in a circle having diameter of 0.2 mm) in plan view. The front surface electrode 15 is formed at an arrangement interval determined in view of the dimension of the conductor ball 50. The front surface electrode 15 is formed at an arrangement interval of a pitch of 0.4 mm, for example.

In the step illustrated in FIG. 3C, a support substrate 92 is laminated on the front surface 11ia side of the semiconductor substrate 11i to cover the multi-layer wiring 12 and the front surface electrode 15. For example, an adhesive 91 is applied on the multi-layer wiring 12 and the front surface electrode 15, and the support substrate 92 is arranged on the adhesive 91. The support substrate 92 can use that formed with a material having glass or silicon as a main component, for example. The support substrate 92 has a thickness corresponding to the supporting rigidity necessary for stably supporting the semiconductor substrate 11i.

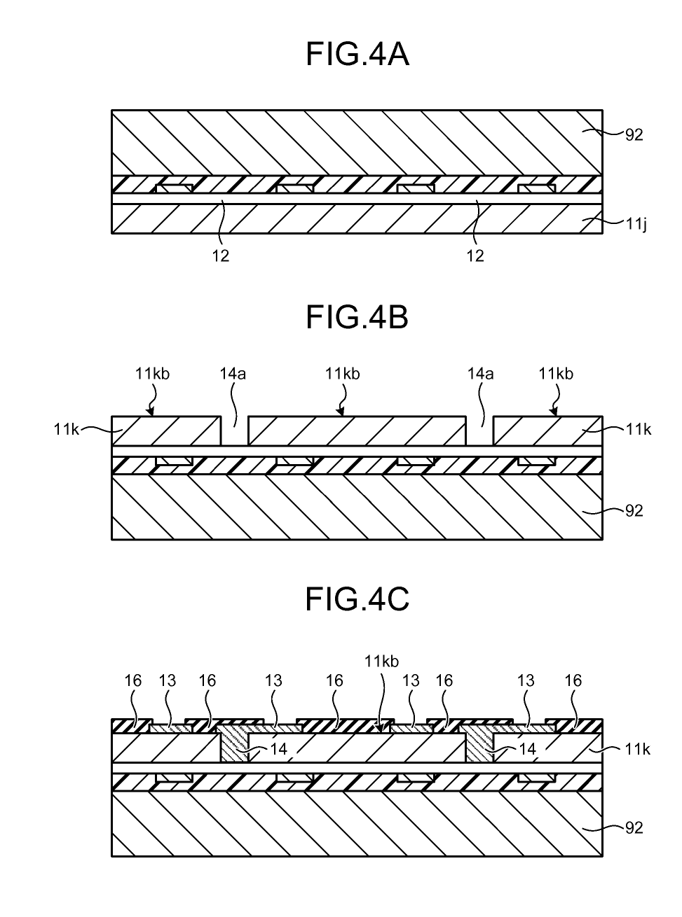

In the step illustrated in FIG. 4A, the semiconductor substrate 11i is thinned from the back surface 11ib side with the support substrate 92 laminated thereto. For example, the semiconductor substrate 11i (see FIG. 3C) having the back surface 11ib on the lower side is arranged on a polishing pad, the semiconductor substrate 11i is pushed down from the upper side, and the semiconductor substrate 11i is polished with the rotating polishing pad. The thinned semiconductor substrate 11j is thereby obtained.

In the step illustrated in FIG. 4B, a hole 14a for embedding the through silicon via 14 is formed in the region where the through silicon via 14 is to be formed in the semiconductor substrate 11j. For example, the semiconductor substrate 11j is inverted, and etching is carried out with respect to the semiconductor substrate 11j by RIE, and the like using a resist pattern RP2 (not illustrated) having an opening pattern corresponding to the region where the through silicon via 14 is to be formed as a mask to form the hole 14a in the semiconductor substrate 11j. The resist pattern RP2 is then removed.

In the step illustrated in FIG. 4C, an insulating layer (not illustrated) is formed on the hole 14a and a back surface 11kb of the semiconductor substrate 11k to electrically insulate the through silicon via 14 and the back surface wiring 13 to be formed later from the semiconductor substrate 11k. Thereafter, the through silicon via 14 and the back surface wiring 13 are formed. For example, plating is carried out using a resist pattern RP3 (not illustrated) having an opening pattern corresponding to a region where the back surface wiring 13 is to be formed as a mask, the through silicon via 14 is formed in the hole 14a, and the back surface wiring 13 is formed on the back surface 11kb of the semiconductor substrate 11k. The insulating film 16 is deposited on the back surface 11kb of the semiconductor substrate 11k and the back surface wiring 13, and etching is carried out with respect to the insulating film 16i with a resist pattern RP4 (not illustrated) having an opening pattern corresponding to a region where the metal wire 40 is to be joined as a mask. The insulating film 16 (e.g., solder resist) including the opening that partially covers the back surface wiring 13 and selectively exposes the region to which the metal wire 40 is to be joined in the front surface of the back surface wiring 13 thus can be formed. Surface processing of Ni/Au, Ni/Pd/Au, and the like may be performed on the front surface of the back surface wiring 13. The connectability is thereby enhanced in the next step.

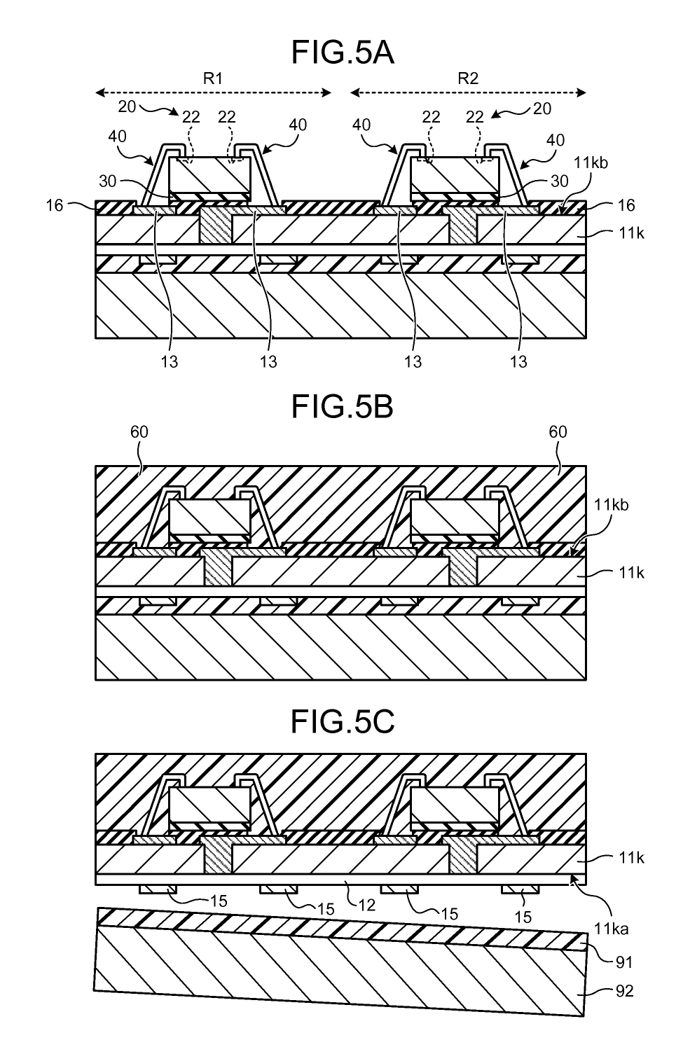

In the step illustrated in FIG. 5A, the semiconductor chip 20 is mounted on the back surface 11kb of the thinned semiconductor substrate 11k, and the wire joining and connecting is carried out. For example, the mount resin 30 is applied to the region where the semiconductor chip 20 is to be arranged in the front surface of the insulating film 16, and the semiconductor chip 20 is arranged on the mount resin 30. One end of the metal wire 40 is joined to the back surface wiring 13, and the other end of the metal wire 40 is joined to the terminal 22 of the semiconductor chip 20. The semiconductor chip 20 is, for example, a memory chip, a logic chip, or a sensor chip. The semiconductor chip 20 includes, for example, a substrate and a multi-layer wiring, and the terminal 22 of the semiconductor chip 20 may be an electrode pad formed on the uppermost wiring layer.

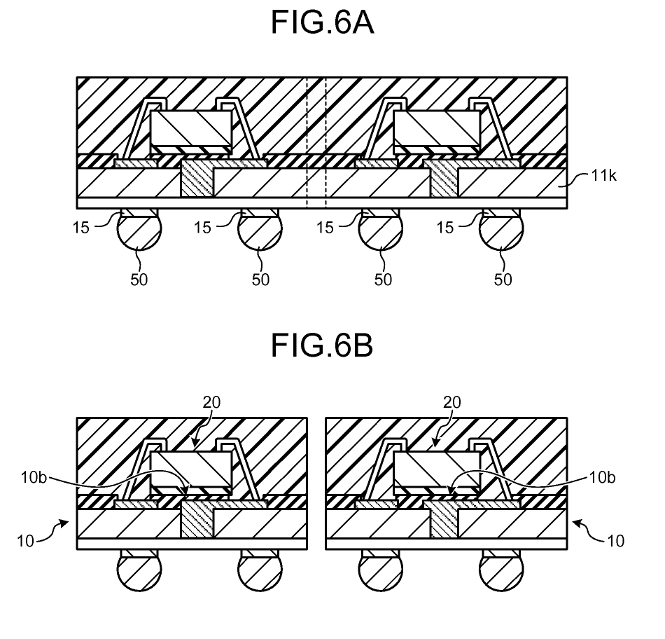

The back surface 11kb of the semiconductor substrate 11k includes a plurality of regions R1, R2 to become the semiconductor chip 10 when the semiconductor substrate 11k is singulated in the step of FIG. 6B, to be described later. In the step illustrated in FIG. 5A, therefore, the semiconductor chip 20 can be mounted for each region R1, R2 to become the semiconductor chip 10. In this case, the semiconductor chips having different functions can coexist for the semiconductor chip 20 for each region R1, R2 to become the semiconductor chip 10.

In the step illustrated in FIG. 5B, the back surface 11kb side of the semiconductor substrate 11k is sealed with the mold resin 60. A thermosetting resin having an insulating property such as epoxy resin, and the like, for example, can be used for the mold resin 60.

In the step illustrated in FIG. 5C, the support substrate 92 is stripped from the semiconductor substrate 11k. If the adhesive 91 is attached to the multi-layer wiring 12 and/or front surface electrode 15, the adhesive 91 may be removed by wet etching with an organic solvent. The front surface of the front surface electrode 15 is thereby exposed.

In the step illustrated in FIG. 6A, the conductor ball 50 is joined on the front surface electrode 15. The conductor ball 50 formed with solder, for example, may be used.

In the step illustrated in FIG. 6B, the portion indicated with a broken line in FIG. 6A is removed by dicing to singulate the semiconductor substrate 11k. A plurality of semiconductor chips 10 in which the semiconductor chip 20 is mounted on the back surface 10b is thereby obtained.

It should be noted that, when causing the front surface electrode 15 to function as an external electrode in the semiconductor device 100, the conductor ball 50 is unnecessary. In this case, the step illustrated in FIG. 6A is omitted.

Consider a case in which the semiconductor chip 20 is mounted on the front surface 10a side (i.e., pad on the uppermost wiring layer M3 of the multi-layer wiring 12) instead of the back surface 10b of the semiconductor chip 10 in the semiconductor device 100. In this case, after the step illustrated in FIG. 4C is completed, the support substrate 92 needs to be stripped from the semiconductor substrate 11j to expose the front surface (i.e., front surface of the uppermost insulating layer DF4) having the multi-layer wiring structure including the multi-layer wiring 12 in the method for manufacturing the semiconductor device 100. The thinned semiconductor substrate 11j is then inverted, the support substrate 92 is adhered to the back surface of the semiconductor substrate 11j, and then the steps corresponding to FIGS. 5A and 5B are carried out, and the support substrate 92 needs to be again stripped from the semiconductor substrate 11k in the step corresponding to the step of FIG. 5C. The troublesome lamination/stripping of the support substrate 92 thus needs to be carried out over plural times, and the number of steps required to manufacture the semiconductor device 100 increases, whereby the manufacturing cost of the semiconductor device 100 may increase. The thinned semiconductor substrate 11j needs to be inverted in a state of not being supported by the support substrate 92 and then again adhered to the support substrate 92, whereby special equipment for handling the thinned semiconductor substrate 11j is required. From this standpoint as well, the manufacturing cost of the semiconductor device 100 may increase.

In the first embodiment, on the other hand, the terminal 22 of the semiconductor chip 20 is electrically connected to the back surface wiring 13 through the metal wire 40 in the semiconductor device 100. The back surface wiring 13 is electrically connected to the multi-layer wiring 12 through the through silicon via 14. The multi-layer wiring 12 is electrically connected to the front surface electrode 15. The front surface electrode 15 or the conductor ball 50 connected to the front surface electrode 15 may function as the external electrode. Thus, the semiconductor chip 20 can be mounted on the back surface of the semiconductor chip 10 while realizing a configuration for the semiconductor chip 20 to exchange signals with the outside. Thus, the number of lamination/stripping of the support substrate 92 can be suppressed to one time in the method for manufacturing the semiconductor device 100, and special equipment for handling the thinned semiconductor substrate 11j becomes unnecessary, whereby the manufacturing cost of the semiconductor device 100 can be reduced. In other words, according to the first embodiment, the semiconductor device 100 suited for reducing the manufacturing cost of the semiconductor device 100 can be provided.

In the first embodiment, the planar dimension of the semiconductor chip 20 is smaller than the planar dimension of the semiconductor chip 10 in the semiconductor device 100. The semiconductor chip 20 is included in the semiconductor chip 10 when seen through from a direction perpendicular to the back surface 10b. Thus, in the semiconductor chip 10, the back surface wiring 13 can be routed to a position not overlapping the semiconductor chip 20 when seen through from a direction perpendicular to the back surface 10b. In other words, the terminal 22 of the semiconductor chip 20 can be electrically connected to the back surface wiring 13 through the metal wire 40.

In the first embodiment, the formation of the through silicon via 14, the formation of the back surface wiring 13, and the mounting of the semiconductor chip 20 can be carried out while maintaining a state in which the support substrate 92 is laminated to the front surface 11ka of the semiconductor substrate 11k in the method for manufacturing the semiconductor device 100. Thus, the number of lamination/stripping of the support substrate 92 can be suppressed to one time in the method for manufacturing the semiconductor device 100, and the special equipment for handling the thinned semiconductor substrate 11j becomes unnecessary, whereby the manufacturing cost of the semiconductor device 100 can be reduced. The time required for the manufacturing of the semiconductor device 100 can also be reduced and the material cost of the adhesive and the support substrate can be reduced, and thus the manufacturing cost of the semiconductor device 100 can be reduced from this standpoint as well.

In the first embodiment, the conductor ball 50 is joined to the front surface electrode 15 in the method for manufacturing the semiconductor device 100. The front surface electrode 15 can be formed with a material (e.g., copper) having a satisfactory joining property with the material (e.g., solder) of the conductor ball 50 than the material (e.g., aluminum) of each wiring layer M1 to M3 in the multi-layer wiring 12. The mounting of the semiconductor device 100 to the set substrate thus can be facilitated.

If the semiconductor chip 20 is mounted on the front surface 10a rather than the back surface 10b of the semiconductor chip 10 in the semiconductor device 100, it is difficult to mount the semiconductor chips 20 having different functions for every region to become the semiconductor chip 10 with respect to the same semiconductor substrate 11k. In other words, when attempting to mount the semiconductor chips 20 having different functions, the manufacturing cost of the semiconductor device 100 may increase since re-designing of the multi-layer wiring 12 is required.

In the first embodiment, on the other hand, the semiconductor chips 20 having different functions can be mounted for every region to become the semiconductor chip 10 with respect to the same semiconductor substrate 11k in the method for manufacturing the semiconductor device 100. For example, when changing the layout pattern of the multi-layer wiring 12, a need to re-design the circuit in the multi-layer wiring 12 arises such as changing the layout pattern of the adjacent circuit. On the contrary, when changing the layout pattern of the back surface wiring 13, the change of the layout pattern of the circuit in the multi-layer wiring 12 is unnecessary, and the re-designing of the circuit in the multi-layer wiring 12 is unnecessary. In other words, the layout pattern suited for the different functions can be acquired with the back surface wiring 13, so that the change of the layout configuration corresponding to the semiconductor chips 20 having different functions can be realized without re-designing the multi-layer wiring 12. As a result, the manufacturing cost of the semiconductor device 100 can be reduced.

It should be noted that, although not illustrated, in the semiconductor device 100, the semiconductor chip 10 may have a configuration in which the multi-layer wiring 12 is omitted. In this case, the front surface electrode 15 may be connected to the end on the front surface 11a side in the through silicon via 14. Furthermore, in the method for manufacturing the semiconductor device 100, the process of forming the multi-layer wiring 12 may be omitted in the step illustrated in FIG. 3A, and the front surface electrode 15 may be formed in a region where the through silicon via 14 is to be formed in the step illustrated in FIG. 3B.

### Second Embodiment

A semiconductor device 200 according to a second embodiment will now be described. The portions different from the first embodiment will be centrally described below.

In the first embodiment, the semiconductor chip 20 is wire joined and connected to the back surface 10b of the semiconductor chip 10, but in the second embodiment, a semiconductor chip 220 is flip-chip connected to the back surface 10b of the semiconductor chip 10.

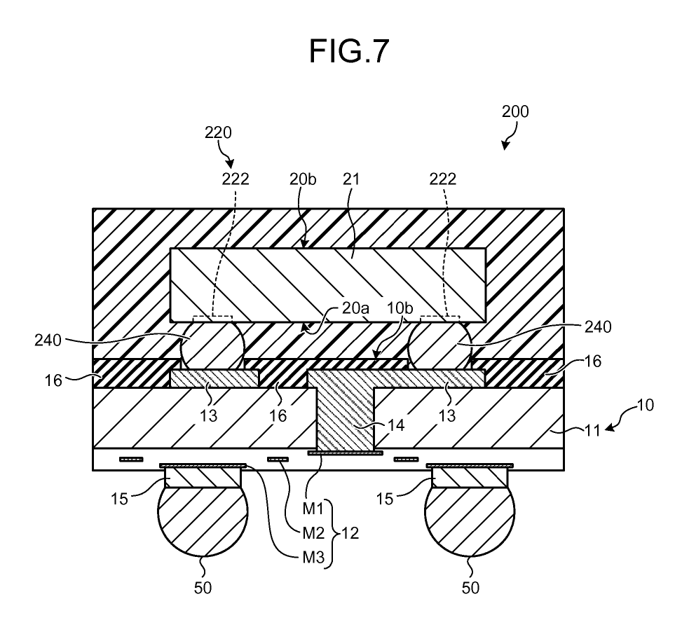

Specifically, as illustrated in FIG. 7, the semiconductor device 200 includes the semiconductor chip 220 and a conductor bump 240 in place of the semiconductor chip 20 and the metal wire 40 (see FIG. 1).

The semiconductor chip 220 is mounted on the back surface 10b of the semiconductor chip 10. For example, the semiconductor chip 220 is mounted on the back surface 10b of the semiconductor chip 10 with the front surface 20a facing the semiconductor chip 10.

A terminal 222 of the semiconductor chip 220 may be an electrode pad formed on the uppermost wiring layer in the multi-layer wiring. The terminal 222 of the semiconductor chip 220 may have a size and shape corresponding to the conductor bump 240. The terminal 222 of the semiconductor chip 220 may be arranged at a peripheral region in the front surface 20a. In this case, the planar dimension of the semiconductor chip 220 is smaller than the planar dimension of the semiconductor chip 10. The semiconductor chip 220 is included in the semiconductor chip 10 when seen through from the direction perpendicular to the back surface 10b. Thus, in the semiconductor chip 10, the back surface wiring 13 can be extended to a position (i.e., position corresponding to the terminal 222 where the conductor bump 240 is joined in FIG. 7) corresponding to the peripheral region in the front surface 20a of the semiconductor chip 220 when seen through from the direction perpendicular to the back surface 10b. In other words, the terminal 222 of the semiconductor chip 220 can be electrically connected to the back surface wiring 13 by way of the conductor bump 240.

The conductor bump 240 electrically connects the terminal 222 of the semiconductor chip 220 and the back surface wiring 13 of the semiconductor chip 10. The conductor bump 240 is formed with a solder, for example.

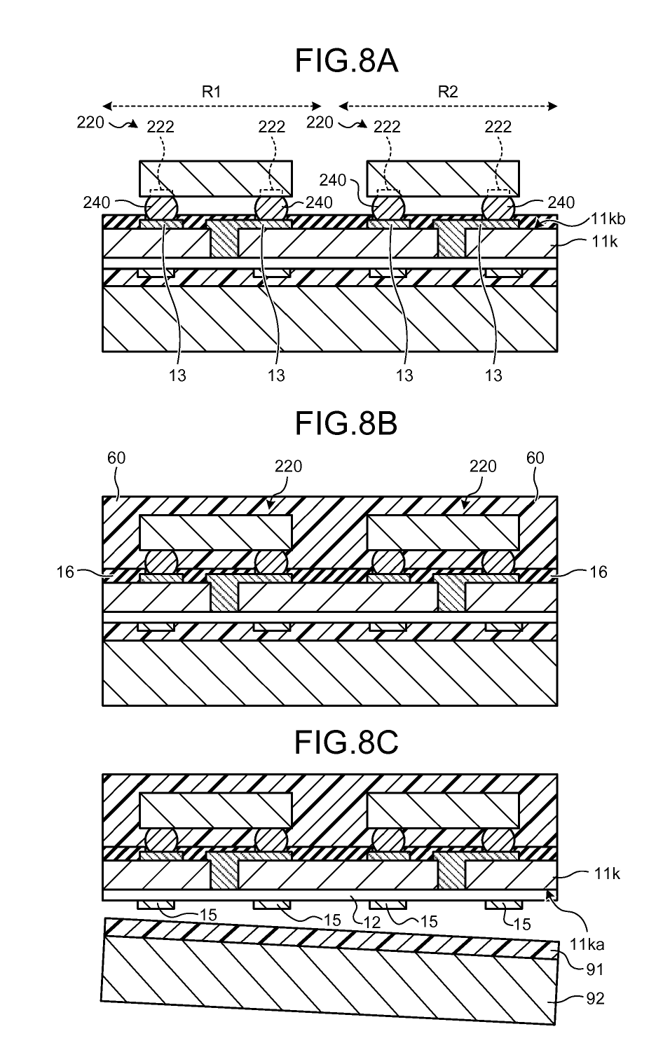

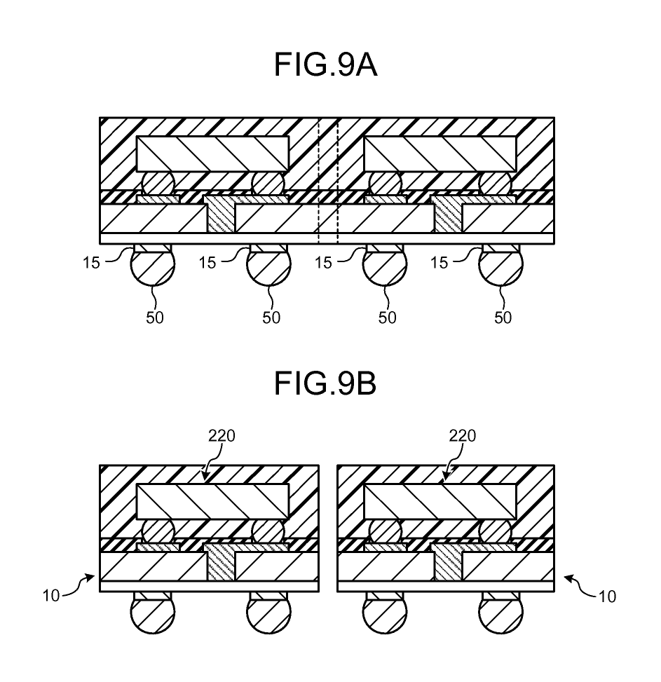

As illustrated in FIGS. 8A to 9B, the method for manufacturing the semiconductor device 200 differs from the first embodiment in the following points. FIGS. 8A to 8C, 9A, and 9B are step cross-sectional views illustrating the method for manufacturing the semiconductor device 200.

After the steps illustrated in FIGS. 3A to 3C, and 4A to 4C are carried out, steps illustrated in FIGS. 8A to 8C, 9A, and 9B are carried out in the method for manufacturing the semiconductor device 200.

In the step illustrated in FIG. 8A, the semiconductor chip 220 is mounted on the back surface 11kb of the thinned semiconductor substrate 11k, and the flip-chip connection is carried out. For example, the conductor bump 240 is joined to the region where the terminal 222 of the semiconductor chip 220 is to be arranged in the front surface of the back surface wiring 13, and the semiconductor chip 220 is arranged on the conductor bump 240. The conductor bump 240 may be formed with the solder, for example.

In this case, the positions of the semiconductor chip 220 and the conductor bump 240 are aligned, and the terminal 222 of the semiconductor chip 220 is joined to the conductor bump 240. The semiconductor chip 220 is, for example, a memory chip, a logic chip, or a sensor chip.

It should be noted that the semiconductor chip 220 can be mounted on every region R1, R2 to become the semiconductor chip 10 in the back surface 11kb of the semiconductor substrate 11k. In this case, the semiconductor chips having different functions can coexist for the semiconductor chip 220 for every region R1, R2 to become the semiconductor chip 10.

In the step illustrated in FIG. 8B, the back surface 11kb side of the semiconductor substrate 11k is sealed with the mold resin 60. A thermosetting resin having an insulating property such as epoxy resin, and the like, for example, can be used for the mold resin 60. In this case, a gap of the semiconductor chip 220 and the insulating film 16 is also sealed with the mold resin 60.

In the step illustrated in FIG. 8C, the support substrate 92 is stripped from the semiconductor substrate 11k. If the adhesive 91 is attached to the multi-layer wiring 12 and the front surface electrode 15, the adhesive 91 may be removed by wet etching with an organic solvent. The front surface of the front surface electrode 15 is thereby exposed.

In the step illustrated in FIG. 9A, the conductor ball 50 is joined to the front surface electrode 15. The conductor ball 50 formed with the solder, for example, may be used.

In the step illustrated in FIG. 9B, the portion indicated with a broken line in FIG. 6A is removed by dicing to singulate the semiconductor substrate 11k. A plurality of semiconductor chips 10 in which the semiconductor chip 220 is mounted on the back surface 10b is thereby obtained.

Therefore, in the second embodiment, the terminal 222 of the semiconductor chip 220 is electrically connected to the back surface wiring 13 by way of the conductor bump 240 in the semiconductor device 200. The back surface wiring 13 is electrically connected to the multi-layer wiring 12 through the through silicon via 14. The multi-layer wiring 12 is electrically connected to the front surface electrode 15. The front surface electrode 15 or the conductor ball 50 connected to the front surface electrode 15 may function as the external electrode. Thus, the semiconductor chip 220 can be mounted on the back surface of the semiconductor chip 10 while realizing the configuration for the semiconductor chip 220 to exchange signals with the outside. Thus, the number of lamination/stripping of the support substrate 92 can be suppressed to one time in the method for manufacturing the semiconductor device 200, and special equipment for handling the thinned semiconductor substrate 11j becomes unnecessary, whereby the manufacturing cost of the semiconductor device 200 can be reduced. In other words, according to the second embodiment as well, the semiconductor device 200 suited for reducing the manufacturing cost of the semiconductor device 200 can be provided.

### Third Embodiment

A semiconductor device 300 according to a third embodiment will now be described. The portions different from the first embodiment will be centrally described.

In the first embodiment, one semiconductor chip 20 is mounted on the back surface 10b of the semiconductor chip 10, but in the third embodiment, a plurality of semiconductor chips 20, 320 are mounted on the back surface 10b of a semiconductor chip 310.

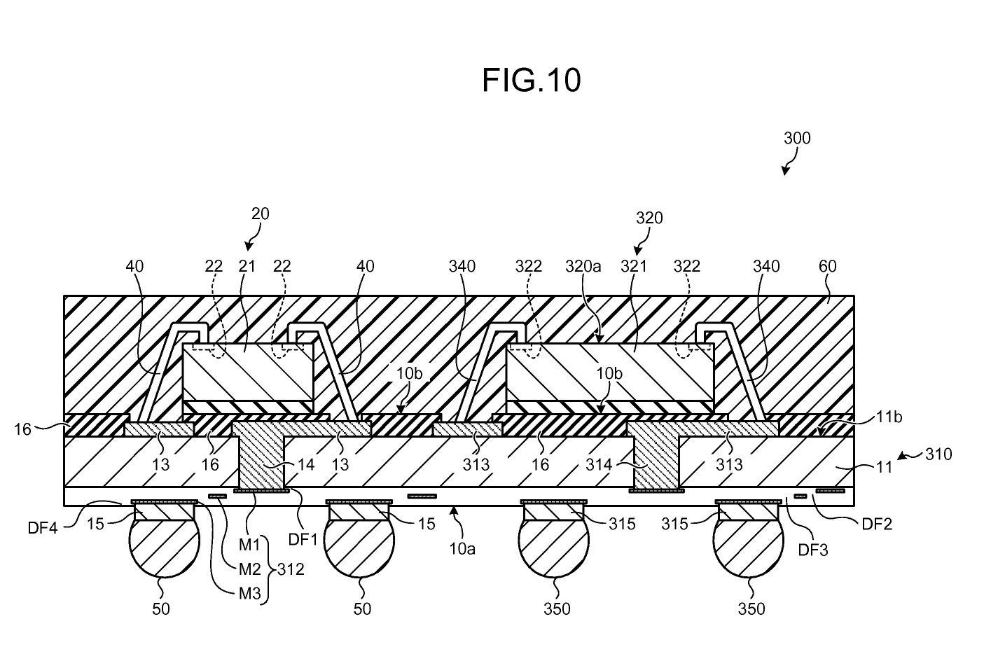

Specifically, as illustrated in FIG. 10, the semiconductor device 300 includes the semiconductor chip 310 in place of the semiconductor chip 10 (see FIG. 1), and further includes a semiconductor chip 320, a metal wire 340, and a conductor ball 350.

The semiconductor chip 310 includes a multi-layer wiring 312 in place of the multi-layer wiring 12 (see FIG. 1), and further includes a back surface wiring 313, a through silicon via 314, and a front surface electrode 315.

The back surface wiring 313 is arranged at a position corresponding to the semiconductor chip 320 on the back surface 11b of the substrate 11. The back surface wiring 313 is electrically connected to the through silicon via 314, and is routed to a predetermined position in the back surface 11b from above the through silicon via 314. For example, if the through silicon via 314 is arranged at a position overlapping the semiconductor chip 320 when seen through from the direction perpendicular to the back surface 11b, the back surface wiring 313 is routed to the position not overlapping the semiconductor chip 320. The metal wire 340 is joined to the back surface wiring 313. A terminal 322 of the semiconductor chip 320 is electrically connected to the back surface wiring 313 through the metal wire 340. The back surface wiring 313 is formed with a material having copper as a main component, for example.

The multi-layer wiring 312 is arranged on the front surface 11a of the substrate 11. The multi-layer wiring 312 includes a plurality of wiring layers M1 to M3 and the plug wiring (not illustrated) for connecting the same. In this case, the multi-layer wiring 312 includes a wiring corresponding to the semiconductor chip 320 in addition to the wiring corresponding to the semiconductor chip 20. Insulating layers DF1 to DF4 and the wiring layers M1 to M3 are alternately and repeatedly stacked on the front surface 11a of the substrate 11 to form the multi-layer wiring structure. Each wiring layer M1 to M3 is formed with a material having aluminum as a main component, for example. Each insulating layer DF1 to DF4 is formed with a material having oxide silicon as a main component, for example.

The through silicon via 314 is passed through the substrate 11 from the back surface 11b to the front surface 11a. The through silicon via 314 electrically connects the back surface wiring 313 and the multi-layer wiring 312. The through silicon via 314 is formed with a material having copper as a main component, for example. The end on the front surface 11a side of the substrate 11 in the through silicon via 314 can be connected to the lowermost wiring layer M1 in the multi-layer wiring 312.

The front surface electrode 315 is arranged on the multi-layer wiring 312, and is electrically connected to the multi-layer wiring 312. For example, the front surface electrode 315 can be arranged on the uppermost wiring layer M3 in the multi-layer wiring 312. The front surface electrode 315 can be formed with a material having satisfactory joining property with the material (e.g., solder) of the conductor ball 350 than the material (e.g., aluminum) of each wiring layer M1 to M3 in the multi-layer wiring 312. The front surface electrode 315 may be formed with a material having copper as a main component, or may be formed with a material having nickel/gold alloy as a main component.

The front surface electrode 315 has a planar dimension and shape corresponding to the conductor ball 350. The front surface electrode 315 may, for example, have a circular shape (e.g., circular shape having diameter of 0.2 mm) or a rectangular shape (rectangular shape included in a circle having diameter of 0.2 mm) in plan view. The front surface electrode 315 is arranged at an arrangement interval determined in view of the dimension of the conductor ball 350. The front surface electrode 315 is arranged at an arrangement interval of a pitch of 0.4 mm, for example.

The semiconductor chip 320 is arranged to line with the semiconductor chip 20 along the back surface 10b of the semiconductor chip 310, and is mounted on the back surface 10b of the semiconductor chip 310. For example, the semiconductor chip 320 is mounted on the back surface 10b of the semiconductor chip 310 with the front surface 320a facing the side opposite to the semiconductor chip 310. The back surface 20b of the semiconductor chip 20 is adhered to the back surface 10b (front surface of the insulating film 16) of the semiconductor chip 310 with the mount resin 30. The planar dimension of the semiconductor chip 320 is smaller than the planar dimension of the semiconductor chip 310. The semiconductor chip 320 is included in the semiconductor chip 310 when seen through from the direction perpendicular to the back surface 10b. Thus, in the semiconductor chip 310, the back surface wiring 313 can be routed to a position not overlapping the semiconductor chip 320 when seen through from the direction perpendicular to the back surface 10b. In other words, the terminal 322 of the semiconductor chip 320 can be electrically connected to the back surface wiring 313 through the metal wire 340. The semiconductor chip 320 includes a chip main body 321 with a substrate and a multi-layer wiring, for example. The multi-layer wiring can be arranged on the front surface 320a side with respect to the substrate. The terminal 322 of the semiconductor chip 320 can be assumed as an electrode pad formed on the uppermost wiring layer in the multi-layer wiring.

The metal wire 340 electrically connects the terminal 322 of the semiconductor chip 320 and the back surface wiring 313 of the semiconductor chip 310. The metal wire 340 is formed with a material having copper or gold as a main component, for example.

The conductor ball 350 is joined to the front surface electrode 315, and functions as an external electrode. For example, when the semiconductor device 300 is mounted on the set substrate, the conductor ball 350 functions as an electrode connected to the set substrate. The conductor ball 350 is formed with a solder, for example.

In the semiconductor device 300, the semiconductor chip 310, the semiconductor chip 20, and the semiconductor chip 320 are assumed to have similar functions with each other. Alternatively, a part of the semiconductor chip 310, the semiconductor chip 20, and the semiconductor chip 320 may have similar functions, and another part may have different functions. Furthermore, the semiconductor chip 310, the semiconductor chip 20, and the semiconductor chip 320 may have functions different from each other and associated with each other. Each of the semiconductor chip 20 and the semiconductor chip 320 is a memory chip, a logic chip, or a sensor chip, for example. The sensor may be an acceleration sensor, a magnetic sensor, an optical sensor, and the like.

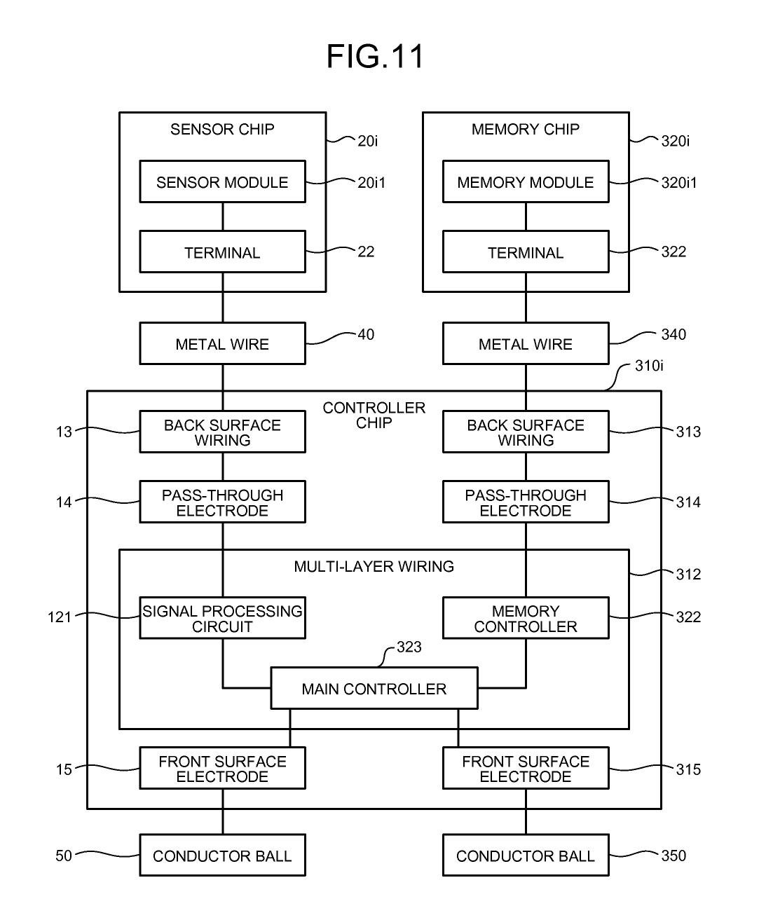

When the semiconductor chip 20 is a sensor chip 20i, and the semiconductor chip 320 is a memory chip 320i, the semiconductor chip 310 may be a controller chip 310i including a signal processing circuit for processing the signal of the sensor chip 20i and a memory controller for controlling the memory chip 320i. In this case, the semiconductor device 300 can be configured as illustrated in FIG. 11.

The sensor chip 20i includes an acceleration sensor, a geomagnetic sensor, and the like, for example. The sensor chip 20i includes the sensor module 20i1 and the terminal 22. The sensor module 20i1 is configured to detect a predetermined physical quantity. For example, if the sensor chip 20i is the acceleration sensor, the sensor module 20i1 includes a diaphragm and a piezo resistance element, where the piezo resistance element detects the position change of the diaphragm and outputs the detected signal to the terminal 22. For example, if the sensor chip 20i is the geomagnetic sensor, the sensor module 20i1 includes a current source and a Hall element, where the Hall element detects the magnitude and the direction of the geomagnetism while the current is supplied from the current source and outputs the detected signal to the terminal 22.

The signal output to the terminal 22 is transmitted to the back surface wiring 13 of the controller chip 310i through the metal wire 40. The signal transmitted to the back surface wiring 13 is transmitted to the multi-layer wiring 312 through the through silicon via 14. The signal transmitted to the multi-layer wiring 312 is transmitted to the signal processing circuit 121 in the multi-layer wiring 312 through a predetermined wiring in the multi-layer wiring 312. The signal processing circuit 121 processes the signal and converts the signal into a signal recognizable at outside (e.g., host device to which the semiconductor device 100 is connected) and transmits the signal to the main controller 323.

The main controller 323 transmits the signal received from the signal processing circuit 121 to the front surface electrode 15 when determined to output the current value of the physical quantity detected with the sensor chip 20i. The signal transmitted to the front surface electrode 15 is output to the outside through the conductor ball 50.

The main controller 323 provides the signal received from the signal processing circuit 121 to the memory controller 322 when determining to accumulate the current value of the physical quantity detected with the sensor chip 20i as history information. The memory controller 322 writes the data corresponding to the signal indicating the current value of the physical quantity to the memory cell in the memory module 320i1 through the through silicon via 314, the back surface wiring 313, the metal wire 340, and the terminal 322.

When determining to process the accumulated history information to obtain the trend information of the physical quantity, for example, the main controller 323 provides a command instructing the same to the memory controller 322. The memory controller 322 reads out the data of the history information from the memory module 320i1 through the terminal 322, the metal wire 340, the back surface wiring 313, and the through silicon via 314, and provides the read data of the history information to the main controller 323 in accordance with the command. The memory controller 322 obtains the trend information of the physical quantity based on the data of the history information, and transmits the signal corresponding to the obtained trend information to the front surface electrode 315. The signal transmitted to the front surface electrode 315 is output to the outside through the conductor ball 350.

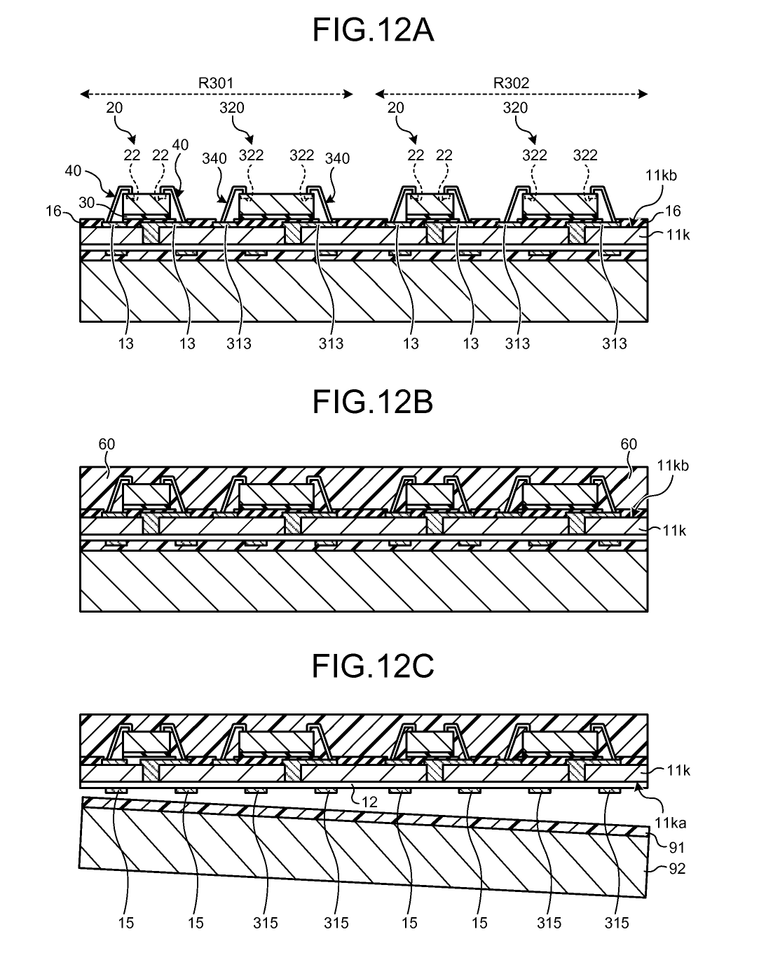

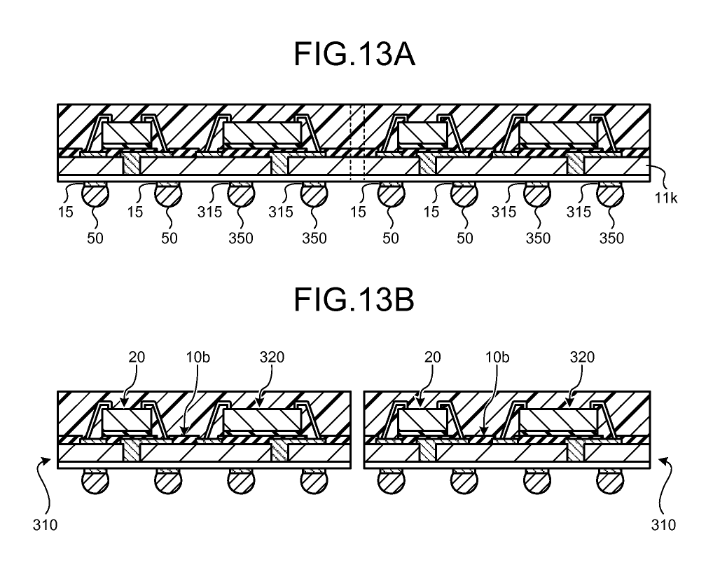

As illustrated in FIGS. 12A to 13B, the method for manufacturing the semiconductor device 300 differs from the first embodiment in the following points. FIGS. 12A to 12C, 13A, and 13B are step cross-sectional views illustrating the method for manufacturing the semiconductor device 300.

After the steps illustrated in FIGS. 3A to 3C, and 4A to 4C are carried out, steps illustrated in FIGS. 12A to 12C, 13A, and 13B are carried out in the method for manufacturing the semiconductor device 300.

In the step illustrated in FIG. 12A, the semiconductor chip 20 and the semiconductor chip 320 are mounted on the back surface 11kb of the thinned semiconductor substrate 11k, and the wire joining and connecting is carried out.

For example, the mount resin 30 is applied to the region where the semiconductor chip 20 is to be arranged in the front surface of the insulating film 16, and the semiconductor chip 20 is arranged on the mount resin 30. One end of the metal wire 40 is joined to the back surface wiring 13, and the other end of the metal wire 40 is joined to the terminal 22 of the semiconductor chip 20. The semiconductor chip 20 is a memory chip, a logic chip, or a sensor chip, for example. The semiconductor chip 20 includes a substrate and a multi-layer wiring, for example, and the terminal 22 of the semiconductor chip 20 can be assumed as the electrode pad formed on the uppermost wiring layer.

The mount resin 30 is applied to the region where the semiconductor chip 320 is to be arranged in the front surface of the insulating film 16, and the semiconductor chip 320 is arranged on the mount resin 30. One end of the metal wire 340 is joined to the back surface wiring 313, and the other end of the metal wire 340 is joined to the terminal 322 of the semiconductor chip 320. The semiconductor chip 320 is a memory chip, a logic chip, or a sensor chip, for example. The semiconductor chip 320 includes a substrate and a multi-layer wiring, for example, and the terminal 322 of the semiconductor chip 320 can be assumed as the electrode pad formed on the uppermost wiring layer.

The semiconductor chip 20 and the semiconductor chip 320 can be mounted for every region R301, R302 to be the semiconductor chip 310 in the back surface 11kb of the semiconductor substrate 11k. In this case, the semiconductor chips having different functions can coexist for each of the semiconductor chip 20 and the semiconductor chip 320 for every region R301, R302 to become the semiconductor chip 310.

In the step illustrated in FIG. 12B, the back surface 11kb side of the semiconductor substrate 11k is sealed with the mold resin 60. A thermosetting resin having insulating property such as epoxy resin, and the like, for example, can be used for the mold resin 60.

In the step illustrated in FIG. 12C, the support substrate 92 is stripped from the semiconductor substrate 11k. In this case, if the adhesive 91 is attached to the multi-layer wiring 12 and the front surface electrodes 15, 315, the adhesive may be removed by wet etching with an organic solvent. The respective front surfaces of the front surface electrode 15 and the front surface electrode 315 are thereby exposed.

In the step illustrated in FIG. 13A, the conductor ball 50 is joined to the front surface electrode 15, and the conductor ball 350 is joined to the front surface electrode 315. Each of the conductor ball 50 and the conductor ball 350 can be formed with a solder, for example.

In the step illustrated in FIG. 13B, the portion indicated with a broken line in FIG. 13A is removed by dicing to singulate the semiconductor substrate 11k. A plurality of semiconductor chips 310 in which the semiconductor chip 20 and the semiconductor chip 320 are respectively mounted on the back surface 10b is thereby obtained.

As described above, in the third embodiment, a plurality of semiconductor chips 20, 320 is mounted on the back surface 10b of the semiconductor chip 310 in the semiconductor device 300. The semiconductor chip 310, the semiconductor chip 20, and the semiconductor chip 320 thus have functions different from each other and associated with each other. The higher functionality of the semiconductor device 300 thus can be easily realized.

The mounting of the plurality of semiconductor chips 20, 320 to the back surface 10b of the semiconductor chip 310 can be carried out by a flip-chip connection in place of the wire joining and connecting. For example, the terminal 22 of the semiconductor chip 20 may be electrically connected to the back surface wiring 13 through the conductor bump. The terminal 322 of the semiconductor chip 320 may be electrically connected to the back surface wiring 313 through the conductor bump.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor chip; and
a second semiconductor chip mounted on a back surface of the first semiconductor chip; wherein
the first semiconductor chip includes,
a substrate,
a back surface wiring arranged on a back surface of the substrate, the back surface wiring being electrically connected to a terminal of the second semiconductor chip,
a multi-layer wiring arranged on a front surface of the substrate,
a through silicon via configured to electrically connect the back surface wiring and the multi-layer wiring through the substrate, and
a front surface electrode arranged on the multi-layer wiring and electrically connected to the multi-layer wiring.

2. The semiconductor device according to claim 1, wherein
the second semiconductor chip is mounted on a back surface of the first semiconductor chip with a front surface of the second semiconductor chip facing toward a side opposite to the first semiconductor chip, on the front surface of the second semiconductor chip a multi-layer wiring being arranged.

3. The semiconductor chip according to claim 1, wherein
the terminal of the second semiconductor chip is electrically connected to the back surface wiring of the first semiconductor chip through a metal wire.

4. The semiconductor device according to claim 1, wherein
the terminal of the second semiconductor chip is electrically connected to the back surface wiring of the first semiconductor chip through a conductor bump.

5. The semiconductor device according to claim 1, further comprising a conductor ball joined to the front surface electrode.

6. The semiconductor device according to claim 1, wherein
the second semiconductor chip is included in the first semiconductor chip when seen through from a direction perpendicular to the back surface.

7. The semiconductor device according to claim 1, wherein
the first semiconductor chip and the second semiconductor chip have functions associated with each other.

8. The semiconductor device according to claim 7, wherein
the second semiconductor chip is a sensor chip; and
the first semiconductor chip is a controller chip including a signal processing circuit configured to process a signal of the sensor chip.

9. The semiconductor device according to claim 1, further comprising a third semiconductor chip mounted on the back surface of the first semiconductor chip, and having a function different from the second semiconductor chip.

10. The semiconductor device according to claim 9, wherein
the second semiconductor chip and the third semiconductor chip are respectively mounted on the back surface of the first semiconductor chip with the front surface of the second semiconductor chip facing toward the side opposite to the first semiconductor chip, on the front surface of the second semiconductor chip a multi-layer wiring being arranged.

11. The semiconductor device according to claim 9, wherein
the terminal of the second semiconductor chip is electrically connected to a first back surface wiring of the first semiconductor chip by way of a first metal wire, and
a terminal of the third semiconductor chip is electrically connected to a second back surface wiring of the first semiconductor chip by way of a second metal wire.

12. The semiconductor device according to claim 9, wherein
the terminal of the second semiconductor chip is electrically connected to a first back surface wiring of the first semiconductor chip by way of a first conductor bump, and
a terminal of the third semiconductor chip is electrically connected to a second back surface wiring of the first semiconductor chip by way of a second conductor bump.

13. The semiconductor device according to claim 9, wherein
the second semiconductor chip and third semiconductor chip are respectively included in the first semiconductor chip when seen through from a direction perpendicular to the back surface.

14. The semiconductor device according to claim 9, wherein
the first semiconductor chip, the second semiconductor chip, and the third semiconductor chip have functions associated with each other.

15. The semiconductor device according to claim 14, wherein
the second semiconductor chip is a sensor chip;
the third semiconductor chip is a memory chip; and
the first semiconductor chip is a controller chip including a signal processing circuit configured to process a signal of the sensor chip and a memory controller configured to control the memory chip.

16. A method for manufacturing a semiconductor device comprising:
forming a multi-layer wiring on a front surface of a semiconductor substrate;
forming a front surface electrode electrically connected to the multi-layer wiring on the multi-layer wiring;
laminating a support substrate on a front surface side of the semiconductor substrate so as to cover the multi-layer wiring and the front surface electrode;
thinning the semiconductor substrate from a back surface side with the support substrate laminated to the semiconductor substrate;
forming a through silicon via configured to pass through from the back surface to the front surface of the thinned semiconductor substrate and electrically connect to the multi-layer wiring;
forming a first back surface wiring on the back surface of the thinned semiconductor substrate to be electrically connected to the through silicon via;
mounting the first semiconductor chip on the back surface of the thinned semiconductor substrate so that a terminal of the first semiconductor chip is electrically connected to the first back surface wiring;
stripping the support substrate from the thinned semiconductor substrate; and
individualizing the thinned semiconductor substrate, and obtaining a second semiconductor chip, the first semiconductor chip being mounted on the back surface of the second semiconductor chip.

17. The method for manufacturing the semiconductor device according to claim 16, wherein
the forming the multi-layer wiring includes forming an opening configured to expose an uppermost wiring in the multi-layer wiring; and
the forming the front surface electrode includes forming the front surface electrode on a region exposed by the opening in the uppermost wiring.

18. The method for manufacturing the semiconductor device according to claim 16, wherein
the forming of the through silicon via, the forming of the first back surface wiring, and the mounting of the second semiconductor chip are carried out while maintaining a state in which the support substrate is laminated to the front surface of the semiconductor substrate.

19. The method for manufacturing the semiconductor device according to claim 16, further comprising
joining a conductor ball on the front surface electrode.

20. The method for manufacturing the semiconductor device according to claim 16, further comprising
mounting, on the back surface of the thinned semiconductor substrate, a third semiconductor chip having a terminal electrically connected to a second back surface wiring and having a function different from the first semiconductor chip.
